(19) United States
(12) Patent Application Publication
(10) Pub. No.: US 2026/0068602 A1
(43) Pub. Date: Mar. 5, 2026

(54) DEFECT DETECTION IN PACKAGING APPLICATION

(71) Applicant: Applied Materials, Inc., Santa Clara, CA (US)

(72) Inventors: Venkatakaushik VOLETI, San Jose, CA (US); Mehdi VAEZ-IRAVANI, Los Gatos, CA (US)

(21) Appl. No.: 18/817,652

(22) Filed: Aug. 28, 2024

(51) Int. Cl. H01L 21/66; G01N 21/88; G01N 21/95; H01L 21/02; H01L 21/68

(52) U.S. Cl. CPC H01L 22/12; G01N 21/8806; G01N 21/8851; G01N 21/9501; G01N 2021/8861; G01N 2201/0668; G01N 2201/0675

(57) ABSTRACT

An optical inspection system for pre-bonding inspection includes a stage having a surface on which a sample to be inspected is placed, the surface of the sample having a two dimensional (2D) periodic pattern and defects, an optical fiber, a transmissive spatial light modulator (SLM), a measurement lens configured to transmit a beam of light transmitted through the transmissive SLM, a camera configured to detect the transmitted beam of light from the measurement lens, and a measuring beam path through which a beam of light from the optical fiber is incident on and reflected at the surface of the sample on the stage, and transmitted to the transmissive SLM, wherein the transmissive SLM is configured to block the beam of light reflected by the 2D periodic pattern on the surface of the sample.

### CROSS-REFERENCE TO RELATED APPLICATIONS

This application claims priority to U.S. Provisional Application Ser. No. 63/536,366 filed Sep. 1, 2023, and U.S. patent application Ser. No. 18/798,303, filed Aug. 8, 2024, each of which is herein incorporated by reference in its entirety.

### FIELD

Embodiments described herein generally relate to a semiconductor device fabrication process, and more particularly, to pre-bonding inspection in a chip-to-substrate hybrid bonding process.

### BACKGROUND

Chip-to-substrate (C2S) hybrid bonding is a packaging and chip-stacking technique in which pre-diced chiplets are precisely fused onto a larger substrate. Unlike previous bonding techniques, metallic interconnects (e.g., copper) are embedded both in dielectric layers (e.g., SiOₓ) of a chiplet and in dielectric layers on a substrate to which the chiplet is bonded. When brought into contact, the dielectric layers of the chiplet and on the substrate weakly bond with one another almost instantly. A subsequent high-temperature annealing step is then required to fuse of the metallic interconnections, as well as strengthen the bond between the dielectric layers.

The presence of point defects such as particles, chips, cracks, or excessive topographical variations on surfaces of the chiplet and/or the substrate, adversely affect bond quality and give rise to post-bonding defects. These post-bonding defects generally manifest as air gaps of various sizes that impede proper interconnect formation, adversely impact yield, and result in costly wastage of fully manufactured chiplets/substrate. This wastage is particularly severe in use cases where a single substrate may host multiple chiplets (either stacked side-by-side on the substrate, or one-atop-another). However, a pre-bonding inspection to identify such small point defects (e.g., hundreds of nanometers) has been a challenge since optical signals from small point defects is buried in large optical signals from features (e.g., metallic interconnects) in certain geometrical patterns formed in the large substrate having a width or diameter of about 300 mm.

Accordingly, there is a need for a pre-bonding inspection system that can effectively detect small pre-bonding point defects while reducing the obscuring effect of signals generated from geometrical patterns formed on a substrate.

### SUMMARY

Embodiments of the present disclosure provide an optical inspection system for pre-bonding inspection. The optical inspection system includes a stage having a surface on which a sample to be inspected is placed, the surface of the sample having a two dimensional (2D) periodic pattern and defects, an optical fiber, a transmissive spatial light modulator (SLM), a measurement lens configured to transmit a beam of light transmitted through the transmissive SLM, a camera configured to detect the transmitted beam of light from the measurement lens, and a measuring beam path through which a beam of light from the optical fiber is incident on and reflected at the surface of the sample on the stage, and transmitted to the transmissive SLM, wherein the transmissive SLM is configured to block the beam of light reflected by the 2D periodic pattern on the surface of the sample.

Embodiments of the present disclosure also provide an optical inspection system for pre-bonding inspection. The optical inspection system includes a stage having a surface on which a sample to be inspected is placed, the surface of the sample having a two dimensional (2D) periodic pattern and defects, an optical fiber, a reflective spatial light modulator (SLM), a measurement lens configured to transmit a beam of light reflected at the reflective SLM, a camera configured to detect the transmitted beam of light from the measurement lens, and a measuring beam path through which a beam of light from the optical fiber is incident on and reflected at the surface of the sample on the stage, and transmitted to the reflective SLM, wherein the reflective SLM is configured to block the beam of light reflected by the 2D periodic pattern on the surface of the sample.

Embodiments of the present disclosure further provide a method of chip-to-substrate hybrid bonding. The method includes performing a pre-bonding inspection process on a substrate die having metallic bond pads, and a chiplet having metallic bond pads, including generating an optical image of point defects on a surface of the substrate die by an optical inspection system having an optical fiber illumination and a spatial light modulator (SLM), and inspecting the generated optical image, wherein inspecting the generated optical image includes at least one of determining a location of at least one of the point defects on the surface of the substrate die based on the optical image of the point defects on the surface of the substrate die, and determining a location of at least one of the point defects on the surface of the chiplet based on the optical image of the point defects on the surface of the chiplet.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 depicts a process flow diagram of a method of a chip-to-substrate hybrid bonding process, according to one or more embodiments of the present disclosure.

FIGS. 2A, 2B, and 2C are cross-sectional views of a substrate die and a chiplet, corresponding to various states of the method 100 of FIG. 1.

FIGS. 3A, 3B, 3C, 3D, and 3E depict types of samples in which defects and particles formed thereon can be detected by an optical inspection system according to the embodiments described herein.

FIG. 4 is a schematic view of an optical inspection system, according to one or more embodiments of the present disclosure.

FIG. 5 is a schematic view of an optical inspection system, according to one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide systems and methods for performing an optical inspection process to detect small point defects on a chiplet and/or a substrate die to which the chiplet is bonded. Other applications of the optical inspection techniques disclosed herein can include inspection during one or more stages of a wafer-to-wafer bonding process sequence. In the systems described herein, a surface of a sample (e.g., a chiplet, a substrate die, a substrate die with a chiplet bonded thereto, or substrate-die with a substrate-die bonded thereto during a wafer-to-wafer bonding process) is illuminated by coherent light from an optical fiber and optical signal from features (such as metallic bond pads) in a geometrical pattern (e.g., a circular pattern) on a substrate die (e.g., 300 mm wafer) is eliminated or reduced, and thus signal from small defects (e.g., hundreds of nanometers) is enhanced. A map of the defects on the surface of the sample generated from the optical image can be used to identify locations of such small defects and determine corrective actions to perform during a chip-to-substrate hybrid bonding process.

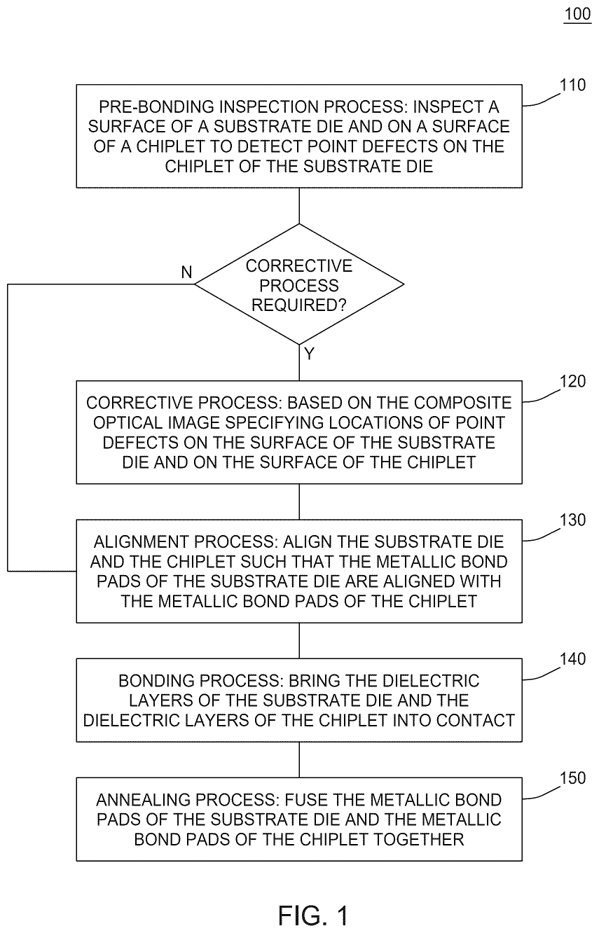

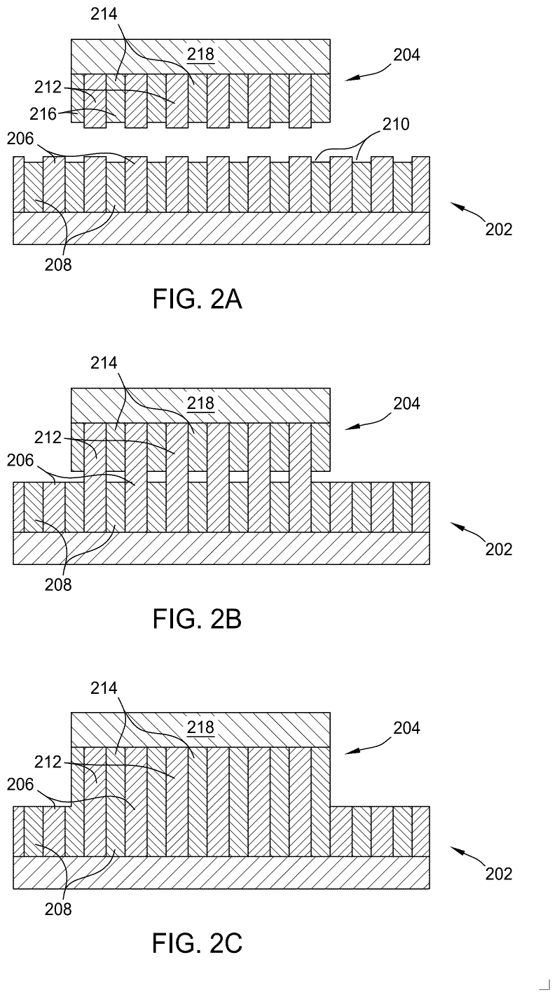

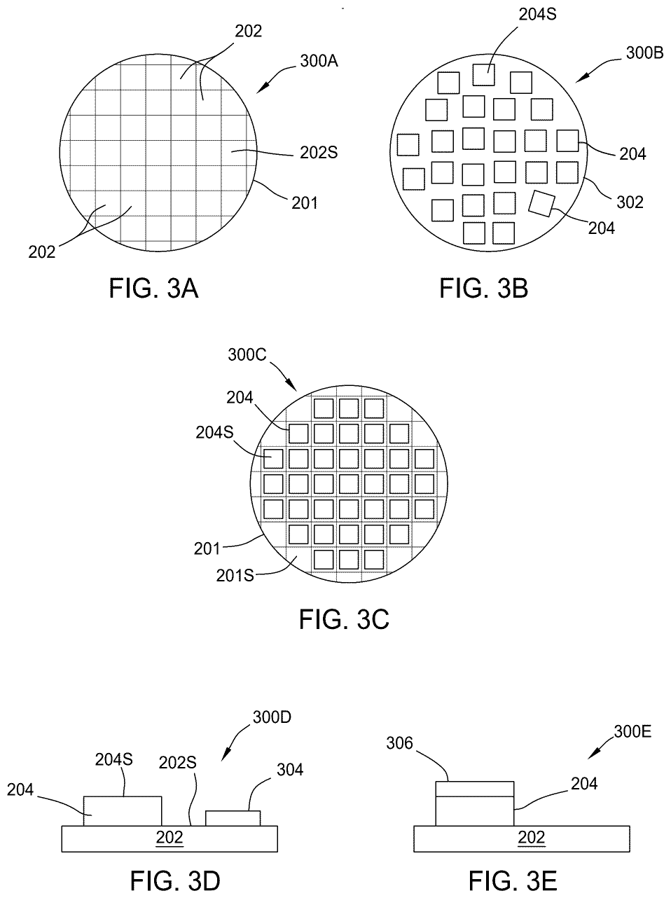

FIG. 1 depicts a process flow diagram of a method 100 of a chip-to-substrate hybrid bonding process, according to one or more embodiments of the present disclosure. FIGS. 2A, 2B, and 2C are cross-sectional views of a substrate die 202 and a chiplet 204 (e.g., a die singulated from another substrate), corresponding to various states of the method 100. In some cases, the substrate die 202 is one portion of a larger substrate 201 (FIG. 3A) that includes a plurality of substrate dies 202 formed therein, wherein the larger substrate 201 can include, for example, a 300 mm, 450 mm, 550 mm, or larger square or round substrate.

As shown in FIG. 2A, the substrate die 202 may include metallic bond pads 208, having features 210, embedded within a dielectric layer 206. The chiplet 204 may include a dielectric layer 212 and metallic bond pads 214, having features 216, embedded within the dielectric layer 212. The dielectric layers 206 and 212 may be formed of silicon dioxide (SiO₂), for example. In one example, the metallic bond pads 208 and the metallic bond pads 214 may be circular and are substantially formed of copper.

The method 100 begins with block 110, in which a pre-bonding inspection process is performed on a surface of the substrate die 202 and on a surface of the chiplet 204, to detect point defects, such as chips, cracks, scratches, organic residues, or other particles positioned on the chiplet 204, and excessive topological variations on the chiplet 204 or the substrate die 202.

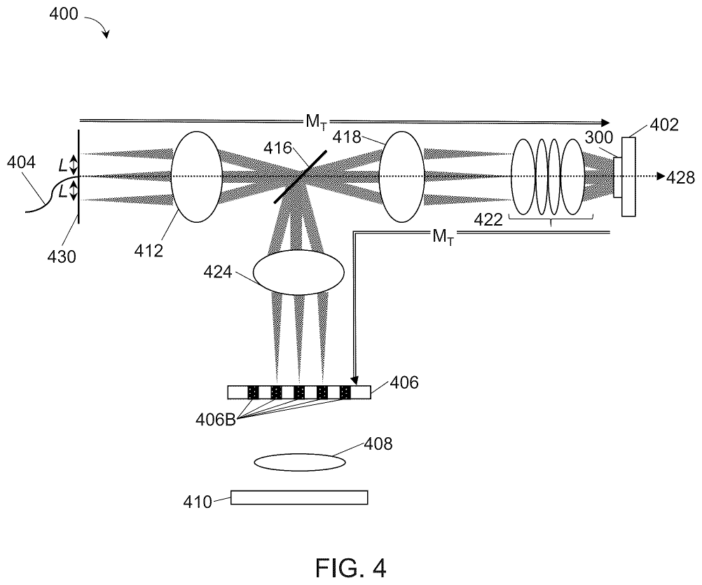

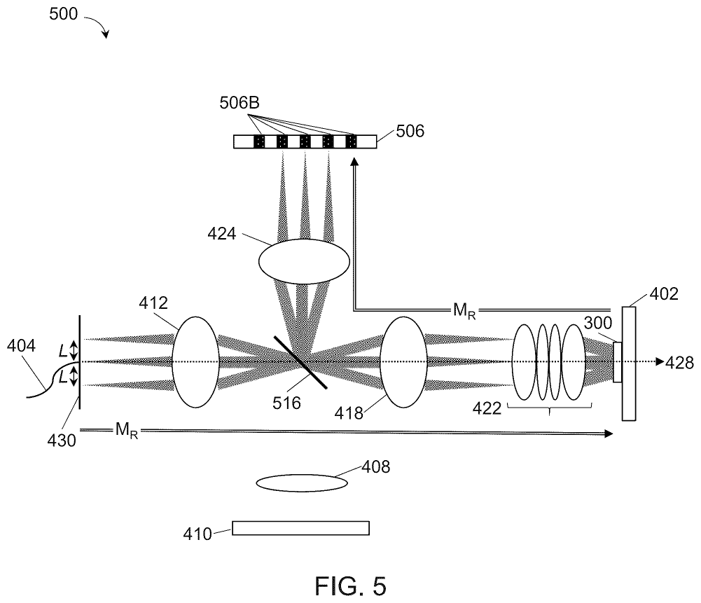

The pre-bonding inspection process includes generating an optical image of a surface of a sample (e.g., a surface of the substrate die 202, a surface of the chiplet 204) by an optical inspection system, such as the optical inspection system 400 (FIG. 4) or the optical inspection system 500 (FIG. 5), having an optical fiber illumination and a spatial light modulator (SLM) in which an optical signal from features in a two dimensional (2D) periodic pattern, such as the metallic bond pads 208 on the substrate die 202 and the metallic bond pads 214 on the chiplet 204, can be eliminated or reduced. The optical image of point defects of the surface of the sample is then reconstructed to generate a map of point defects on the surface of the sample, specifying locations of the point defects on the surface of the sample. The generated map includes information relating to the relative position of the defects found on or within the sample based on pixel coordinate data generated by the optical sensor based on the received optical signal. In some embodiments, a system controller generates a 2D map of the defects found on or within a sample. The generated 2D map contains the position information (e.g., X-Y position information) for the various defects, which can then be used to perform a corrective process.

In block 120, a corrective process is performed based on the optical image specifying locations of point defects on the surface of the substrate die 202 and on the surface of the chiplet 204. The corrective process may include adding or modifying a pre-cleaning process on the surface of the substrate die 202 and/or the surface of the chiplet 204 to remove particles prior to a bonding process, reducing bonding pressures for scratched chiplets in a bonding process to reduce chiplet cracking, depositing additional gapfill material on the surface of the substrate die 202 and/or the surface of the chiplet 204 after a bonding process to ensure coverage of varying chiplet heights, or halting the chip-to-substrate hybrid bonding process, and removing the chiplet 204 for further steps of the chip-to-substrate hybrid bonding process. The corrective process may further include a feed backwards into potentially defective processes outside of a bonder (e.g., CMP, dicing) as a function of wafer location, or time, creating metrics for initial setup, tool qualification and tool-to-tool matching, prompting tool maintenance and re-qualification as a function of increased defectivity over time.

In block 130, an alignment process is performed to align the substrate die 202 and the chiplet 204 such that the metallic bond pads 208 of the substrate die 202 are aligned with the metallic bond pads 214 of the chiplet 204.

In block 140, as shown in FIG. 2B, a bonding process is performed to bring the surface of the substrate die 202 and the surface of the chiplet 204 into contact. When brought into contact, the dielectric layer 206 of the substrate die 202 and the dielectric layer 212 of the chiplet 204 weakly bond to one another.

In block 150, as shown in FIG. 2C, an annealing process is performed to fuse the metallic bond pads 208 of the substrate die 202 and the metallic bond pads 214 of the chiplet 204 together. A high temperature anneal step fuses the metallic bond pads 208 and the metallic bond pads 214, as well as strengthen the bonding of the dielectric layer 206 of the substrate die 202 and the dielectric layer 212 of the chiplet 204. Electrical circuits (not shown) on the bottom of the substrate die 202 are then connected to electrical circuits 218 formed in the chiplet 204.

During the chip-to-substrate hybrid bonding process, the presence of point defects on the chiplet 204 or the substrate die 102, affect fidelity of the chip-to-substrate hybrid bonding and give rise to post-bonding defects. The post-bonding defects generally manifest as air gaps that impede proper interconnect formation or form broken circuits, which will adversely impact device yield, and result in the costly need to scrap the fully manufactured chiplet/substrate dies. The created waste is particularly severe in use cases where a single substrate die 202 may host multiple chiplets (either stacked side-by-side on the substrate, or one-atop-another).

The embodiments described herein provide an optical inspection system that can effectively detect point defects while eliminating or reducing the effect of the optical signal received from background (e.g., optical signals from the substrate having features in a periodic pattern formed thereon), such that the point defects can be addressed and/or resolved during a chip-to-substrate hybrid bonding process.

FIGS. 3A, 3B, 3C, 3D, and 3E depict types of samples in which defects and particles formed thereon can be detected by an optical inspection system according to the embodiments described herein.

FIG. 3A depicts a first type sample 300A to be inspected, which includes a substrate 201 that includes a plurality of substrate dice 202 to which chiplets 204 can be bonded.

FIG. 3B depicts a second type sample 300B to be inspected, which includes singulated and unbonded chiplets 204 on a carrier 302. The carrier 302 may be a tape frame. The chiplets 204 have been diced or sawed, and mounted to the carrier 302, to be transferred to the substrate die 202 during a bonding process. Although the carrier 302 sufficiently holds the chiplet 204 during a singulation process, the chiplets 204 are not always positioned in an aligned manner due to the singulation process which destroys the lithography-defined alignment, and further due to the flexibility of the carrier 302. Thus, some of the chiplets 204 may be skewed relative to each other. In one example, the chiplets 204 are misaligned relative to each other in a plane that is parallel to the top surface 204S of the chiplets 204. However, in some cases the top surfaces 204S of the chiplets 204 are misaligned relative to each other, wherein the misalignment can include a spacing in the X, Y and Z directions misalignment and also an angular misaligned such as a pitch, yaw and roll angular orientation misalignment. For example, as the carrier 302 flexes, top surfaces 204S of the chiplets 204 vary in height relative to each other.

FIG. 3C depicts a third type sample 300C to be inspected, which includes singulated chiplets 204 bonded to a top surface 202S of the substrate die 202 (shown in FIG. 3A). FIG. 3D depicts a fourth type sample 300D to be inspected, which includes a substrate die 202 having a singulated chiplet 204 bonded thereon, and a chiplet 304 having a different height from the chiplet 204 to be bonded to the substrate die 202. In some cases, as shown in FIG. 3D, the top surfaces 204S of the singulated chiplets 204 and the top surface 202S of the substrate die 202 present a substantial height difference that must be overcome when optically scanning top surfaces of the third type sample 300C.

FIG. 3E depicts a fifth type sample 300E to be inspected, which includes a singulated chiplet 204 bonded to the substrate die 202 and another singulated chiplet 306 bonded to the singulated chiplet 204.

FIG. 4 is a schematic view of an optical inspection system 400 to inspect a surface of a sample, such as the sample 300, according to one or more embodiments of the present disclosure.

The optical inspection system 400 includes a stage 402 having a surface on which a sample 300 having a two dimensional (2D) periodic pattern and defects to be inspected is placed, an optical fiber 404, a transmissive spatial light modulator (SLM) 406, a measurement lens 408, a camera 410, and a measurement beam path M_{T}, through which a beam of light from the optical fiber 404 is incident on and reflected at a surface of the sample on the stage 402, and transmitted to the transmissive SLM 406. The camera 410 may include digital optical sensors, such as a charge-coupled device (CCD) or an active-pixel sensor (CMOS sensor).

The measurement beam path M_{T} (denoted by double arrows in FIG. 4) includes a first collimator lens 412, a beam splitter 416, a second collimator lens 418, a multi-lens objective 422, and a third collimator lens 424. A surface of the sample 300 on the stage 402 is disposed perpendicular to an optical axis 428 of the first collimator lens 412, the second collimator lens 418, and the multi-lens objective 422. The multi-lens objective 422 consists of a series of lens and mechanical elements designed—in conjunction—to correct optical aberrations (e.g., microscope objective lenses).

In the optical inspection system 400, coherent or partially-coherent illumination light is supplied by the optical fiber 404, whose exit aperture is disposed at a back focal plane 430 of the multi-lens objective 422, relayed onto a separate mechanical plane by a series of lens elements. In some embodiments, the optical fiber 404 is a single-mode optical fiber that carries only a single mode of light (e.g., transverse mode). In some embodiments, the optical fiber 404 has a small core diameter (e.g., between about 5 μm and 500 μm) that delivers laser light. The exit aperture of the optical fiber 404 may be disposed at the optical axis 428, or at a distance L from the optical axis 428 on the back focal plane 430 of the first collimator lens 412, wherein the distance L should not exceed the radius of the back focal plane aperture of the system projected onto the focal plane 430. This distance is chosen to balance a number of factors affecting the sensitivity of the optical system such as: increased collected scattering cross-section of particles, rejection of haze due to surface roughness, and rejection of higher order diffractive orders from repetitive structures such as circular metallic bond pad arrays. By placing the exit aperture of the optical fiber 404 at the optical axis 428, the surface of the sample 300 is illuminated with a normal incident beam of light. A beam of light reflected at the surface of the sample 300 remains on the optical axis 428. By placing the exit aperture of the optical fiber 404 at a distance from the optical axis 428, the surface of the sample 300 is illuminated by a collimated beam of light at an angle θᵢ, and a beam of light reflected at the surface of the sample 300 is shifted off the optical axis 428 by an equivalent amount.

A diverging beam of light from the optical fiber 404 is collimated by the first collimator lens 412, and either travels along the optical axis 428, or travels at an angle relative to the optical axis 428 depending on the distance L of the optical fiber 404 from the optical axis 428, and is then focused by the first collimator lens 412 at a front focal plane of the first collimator lens 412. The beam splitter 416, disposed at the front focal plane of the first collimator lens 412 along the optical axis 428, transmits the focused beam of light from the first collimator lens 412. The second collimator lens 418, whose back focal plane is disposed at or near the beam splitter 416, converges the transmitted beam of light from the beam splitter 416, and converges at a front focal plane of the second collimator lens 418. The multi-lens objective 422 disposed at the front focal plane of the second collimator lens 418 collimates and focuses the converged beam of light from the second collimator lens 418 at the surface of the sample 300 on the stage 402. The focused beam of light from the multi-lens objective 422 is reflected, scattered and diffracted at the surface of the sample 300 on the stage 402, transmitted back through the multi-lens objective 422, the second collimator lens 418, and reflected at the beam splitter 416. The third collimator lens 424 whose back focal plane is disposed at the beam splitter 416 converges the reflected beam of light from the beam splitter 416 at a front focal plane of the third collimator lens 424 disposed at the transmissive SLM 406.

A beam of light from the optical fiber 404 through the measurement beam path M_{T} is scattered by the 2D periodic pattern on the surface of the sample 300 into multiple diffraction orders, with a polar angle θ_{N} from the optical axis 428 given by sin θ_{N}=N (λ/d)+θᵢ, where N denotes the diffraction order number, λ is the wavelength of light and d is the separation of adjacent circular metallic bond pads 208. The diffraction orders are apparent at the back focal plane of the multi-lens objective 422, along with light reflected and scattered from the sample. The back focal plane of the multi-lens objective 422 is relayed onto a transmissive SLM 406. This is accomplished by the reflective path of beam splitter 416, and the set of relay elements (the second collimator lens 418, the third collimator lens 424). The transmissive SLM 406 is a translucent liquid crystal electro-optical display composed of twisted nematic crystals. A voltage signal applied to any of the pixels can—depending on the configuration—change the phase or amplitude transmission of the specific pixel. The diffractive orders converge onto different locations (i.e. pixels) on the transmissive SLM 406 depending on the diffractive order N, where those spots 406B of the transmissive SLM 406 are rendered opaque by an appropriately applied electrical signal. Thus, the beam of light scattered by the 2D periodic pattern on the surface of the sample 300 is blocked from transmitting to the camera 410.

A beam of light from the optical fiber 404 through the measurement beam path M_{T} is scattered by point defects, any imperfections in the circular metallic bond pads 208, or any non-periodic features, such as lines or corners, on the surface of the sample 300 at a different polar angle from the polar angle θ_{N}, where sin θ_{N}=N(λ/d)+θᵢ, for the scattered light by the 2D periodic pattern, and thus transmitted through the transmissive SLM 406 to the camera 410 via the measurement lens 408. The camera 410 detects the transmitted beam of light from the measurement lens 408 to capture images of point defects, any imperfections in the circular metallic bond pads 208, or any non-periodic features, such as lines or corners, on the surface of the sample 300.

FIG. 5 is a schematic view of an optical inspection system 500 to inspect a surface of a sample, such as the sample 300, according to one or more embodiments of the present disclosure. In the optical inspection system 500, a reflective spatial light modulator (SLM) 506 is used in place of the transmissive SLM 406 in the optical inspection system 400. The same reference numerals are used for the components that are substantially the same as those of the optical inspection system 400.

The optical inspection system 500 includes a stage 402 having a surface on which a sample 300 having a two dimensional (2D) periodic pattern and defects to be inspected is placed, an optical fiber 404, the reflective spatial light modulator (SLM) 506, a measurement lens 408, a camera 410, and a measurement beam path M_{R}, through which a beam of light from the optical fiber 404 is incident on and reflected at a surface of the sample on the stage 402, and transmitted to the reflective SLM 506. The camera 410 may include digital optical sensors, such as a charge-coupled device (CCD) or an active-pixel sensor (CMOS sensor).

The measurement beam path M_{R} (denoted by double arrows in FIG. 5) includes a first collimator lens 412, a beam splitter 516, a second collimator lens 418, a multi-lens objective 422, and a third collimator lens 424. A surface of the sample 300 on the stage 402 is disposed perpendicular to an optical axis 428 of the first collimator lens 412, the second collimator lens 418, the second collimator lens 418, and the multi-lens objective 422. The multi-lens objective 422 consists of a series of lens and mechanical elements designed—in conjunction—to correct optical aberrations (e.g., microscope objective lenses).

In the optical inspection system 500, coherent illumination light is supplied by the optical fiber 404, whose exit aperture is disposed at a back focal plane 430 of the first collimator lens 412. In some embodiments, the optical fiber 404 is a single-mode optical fiber that carries only a single mode of light (e.g., transverse mode). In some embodiments, the optical fiber 404 has a small core diameter (e.g., between about 5 μm and 500 μm) that delivers laser light. The exit aperture of the optical fiber 404 may be disposed at the optical axis 428, or at a distance L from the optical axis 428 on the back focal plane 430 of the first collimator lens 412, wherein the distance L should not exceed the radius of the back focal plane aperture of the system projected onto the focal plane 430. This distance is chosen to balance a number of factors affecting the sensitivity of the optical system such as: increased collected scattering cross-section of particles, rejection of haze due to surface roughness, and rejection of higher order diffractive orders from repetitive structures such as circular metallic bond pad arrays. By placing the exit aperture of the optical fiber 404 at the optical axis 428, the surface of the sample 300 is illuminated with a normal incident beam of light. A beam of light reflected at the surface of the sample 300 remains on the optical axis 428. By placing the exit aperture of the optical fiber 404 at a distance from the optical axis 428, the surface of the sample 300 is illuminated by a collimated beam of light, and a beam of light reflected at the surface of the sample 300 is shifted off the optical axis 428.

A diverging beam of light from the optical fiber 404 is collimated by the first collimator lens 412 along the optical axis 428. The beam splitter 516 disposed at the front focal plane of the first collimator lens 412 along the optical axis 428 transmits the focused beam of light from the first collimator lens 412. The second collimator lens 418 whose back focal plane is disposed at the beam splitter 516 defocuses the transmitted beam of light from the beam splitter 516. The second collimator lens 418 converges the defocused beam of light from the second collimator lens 418 at a front focal plane of the second collimator lens 418. The multi-lens objective 422 disposed at the front focal plane of the second collimator lens 418 collimates and focuses the converged beam of light from the second collimator lens 418 at the surface of the sample 300 on the stage 402. The focused beam of light from the multi-lens objective 422 is reflected at the surface of the sample 300 on the stage 402, transmitted back through the multi-lens objective 422, the second collimator lens 418, and the second collimator lens 418, and reflected at the beam splitter 516. The third collimator lens 424 whose back focal plane is disposed at the beam splitter 516 converges the reflected beam of light from the beam splitter 516 at a front focal plane of the third collimator lens 424 disposed at the reflective SLM 506.

A beam of light from the optical fiber 404 through the measurement beam path M_{R} is scattered by the 2D periodic pattern on the surface of the sample 300 into multiple diffraction orders, with a polar angle θ_{N} from the optical axis 428 given by sin θ_{N}=N(λ/d)+θᵢ, where N denotes the diffraction order number, λ is the wavelength of light and d is the separation of adjacent circular metallic bond pads 208. The scattered beam of light from the surface of the sample 300 is re-collimated by the second collimator lens 418, focused by the second collimator lens 418 at the back focal plane of the second collimator lens 418, reflected by the beam splitter 516, and converged on the reflective SLM 506 at different spots depending on the diffraction order N, where those spots 506B of the reflective SLM 506 are absorptive. Thus, the beam of light scattered by the 2D periodic pattern on the surface of the sample 300 is blocked from reflecting and transmitting to the camera 410. The reflective spatial light modulators (SLM) 506 are also digital displays with electrically addressable pixels. These pixels can alter either the phase or amplitude of the light that reflects off of them depending on the type of device used. Examples are digital micromirror devices, ferroelectric liquid crystals or nematic liquid crystals.

A beam of light from the optical fiber 404 through the measurement beam path M_{R} is scattered by point defects, any imperfections in the circular metallic bond pads 208, or any non-periodic features, such as lines or corners, on the surface of the sample 300 at a different polar angle from the polar angle θ_{N}, where sin θ_{N}=N(λ/d)+θᵢ, for the scattered light by the 2D periodic pattern, and thus reflected the reflective SLM 506 and transmitted to the camera 410 via the beam splitter 516 and the measurement lens 408. The camera 410 detects the transmitted beam of light from the measurement lens 408 to capture images of point defects, any imperfections in the circular metallic bond pads 208, or any non-periodic features, such as lines or corners, on the surface of the sample 300.

The embodiments described herein provide systems and methods for pre-bonding inspection to identify point defects on a surface of a chiplet and/or a surface of a substrate die to which the chiplet is to be bonded. In the systems described herein, a surface of a sample (e.g., a chiplet, a substrate die, or a substrate die with a chiplet bonded thereto) is illuminated by coherent light from an optical fiber and optical signals from features (such as metallic bond pads) in a geometrical pattern (e.g., a circular pattern) on a substrate die (e.g., 300 mm wafer) is eliminated or reduced, and thus signals from small defects (e.g., tens to hundreds of nanometers) is enhanced. A map of small defects on the surface of the sample generated from the optical image can be used to identify locations of such small defects and determine corrective actions to perform during a chip-to-substrate hybrid bonding process.

While the foregoing is directed to embodiments of the present disclosure, other and further embodiments of the disclosure may be devised without departing from the basic scope thereof, and the scope thereof is determined by the claims that follow.

1. An optical inspection system for pre-bonding inspection, comprising:
a stage having a surface on which a sample to be inspected is placed, the surface of the sample having a two dimensional (2D) periodic pattern and defects;
an optical fiber;
a transmissive spatial light modulator (SLM);
a measurement lens configured to transmit a beam of light transmitted through the transmissive SLM;
a camera configured to detect the transmitted beam of light from the measurement lens; and
a measuring beam path through which a beam of light from the optical fiber is incident on and reflected at the surface of the sample on the stage, and transmitted to the transmissive SLM,
wherein the transmissive SLM is configured to block the beam of light reflected by the 2D periodic pattern on the surface of the sample.

2. The optical inspection system of claim 1, wherein the optical fiber comprises a single-mode optical fiber.

3. The optical inspection system of claim 1, wherein the transmissive SLM comprises a translucent opto-electronic display.

4. The optical inspection system of claim 1, wherein the measuring beam path comprises:
a first collimator lens having a back focal plane disposed at an exit aperture of the optical fiber, the first collimator lens configured to collimate a diverging beam of light from the optical fiber along an optical axis and focus the collimated beam at a front focal plane of the first collimator lens;
a beam splitter disposed at the front focal plane of the first collimator lens along the optical axis and configured to transmit the focused beam of light from the first collimator lens;
a second collimator lens having a back focal plane disposed at the beam splitter, the second collimator lens configured to converge the transmitted beam of light from the beam splitter at the front focal plane of the second collimator lens;
a multi-lens objective disposed at the front focal plane of the second collimator lens, the multi-lens objective configured to collimate and focus the converged beam of light from the second collimator lens at the surface of the sample placed on the stage; and
a third collimator lens having a back focal plane disposed at the beam splitter, the third collimator lens configured to converge the focused beam of light reflected at the surface of the sample placed on the stage, transmitted through the multi-lens objective, and the second collimator lens, and reflected at the beam splitter, at the transmissive SLM.

5. The optical inspection system of claim 4, wherein the exit aperture of the optical fiber is disposed at the optical axis on the back focal plane of the first collimator lens.

6. The optical inspection system of claim 4, wherein the exit aperture of the optical fiber is disposed at a distance from the optical axis on the back focal plane of the first collimator lens.

7. The optical inspection system of claim 4, wherein the multi-lens objective consists of a series of lens and mechanical elements designed to correct optical aberrations.

8. An optical inspection system for pre-bonding inspection, comprising:
a stage having a surface on which a sample to be inspected is placed, the surface of the sample having a two dimensional (2D) periodic pattern and defects;
an optical fiber;
a reflective spatial light modulator (SLM);
a measurement lens configured to transmit a beam of light reflected at the reflective SLM;
a camera configured to detect the transmitted beam of light from the measurement lens; and
a measuring beam path through which a beam of light from the optical fiber is incident on and reflected at the surface of the sample on the stage, and transmitted to the reflective SLM,
wherein the reflective SLM is configured to block the beam of light reflected by the 2D periodic pattern on the surface of the sample.

9. The optical inspection system of claim 8, wherein the optical fiber comprises a single-mode optical fiber.

10. The optical inspection system of claim 8, wherein the reflective SLM comprises digital optical sensors.

11. The optical inspection system of claim 8, wherein the measuring beam path comprises:
a first collimator lens having a back focal plane disposed at an exit aperture of the optical fiber, the first collimator lens configured to collimate a diverging beam of light from the optical fiber along an optical axis;
a beam splitter disposed at a front focal plane of the first collimator lens along the optical axis and configured to transmit the collimated beam of light from the first collimator lens;
a second collimator lens having a back focal plane disposed at the beam splitter, the second collimator lens configured to defocus the transmitted beam of light from the beam splitter;
a second collimator lens having a front focal plane, the second collimator lens configured to converge the defocused beam of light from the second collimator lens at the front focal plane of the second collimator lens;
a multi-lens objective disposed at the front focal plane of the second collimator lens, the multi-lens objective configured to collimate and focus the converged beam of light from the second collimator lens at the surface of the sample placed on the stage; and
a third collimator lens having a back focal plane disposed at the beam splitter, the third collimator lens configured to converge the focused beam of light reflected at the surface of the sample placed on the stage, transmitted through the multi-lens objective, the second collimator lens, and the second collimator lens, and reflected at the beam splitter at the reflective SLM.

12. The optical inspection system of claim 11, wherein the exit aperture of the optical fiber is disposed at the optical axis on the back focal plane of the first collimator lens.

13. The optical inspection system of claim 11, wherein the exit aperture of the optical fiber is disposed at a distance from the optical axis on the back focal plane of the first collimator lens.

14. The optical inspection system of claim 11, wherein the multi-lens objective comprises of a series of lens and mechanical elements designed to correct optical aberrations.

15. A method of chip-to-substrate hybrid bonding, comprising:
performing a pre-bonding inspection process on a substrate die having metallic bond pads, and a chiplet having metallic bond pads, comprising:
generating an optical image of point defects on a surface of the substrate die by an optical inspection system having an optical fiber illumination and a spatial light modulator (SLM); and
inspecting the generated optical image, wherein inspecting the generated optical image comprises at least one of:
determining a location of at least one of the point defects on the surface of the substrate die based on the optical image of the point defects on the surface of the substrate die; and
determining a location of at least one of the point defects on the surface of the chiplet based on the optical image of the point defects on the surface of the chiplet.

16. The method of claim 15, further comprising:
performing a corrective process based on the generated optical image of the point defects on the surface of the chiplet or the generated optical image of the point defects on the surface of the substrate die.

17. The method of claim 16, further comprising:
performing an alignment process, to align the metallic bond pads of the substrate die and the metallic bond pads of the chiplet; and
performing a bonding process, to bring the surface of the substrate die and the surface of the chiplet into contact.

18. The method of claim 16, wherein the corrective process comprises:
adding or modifying a pre-cleaning process on the surface of the substrate die and/or the surface of the chiplet to remove particles prior to the bonding process;
reducing bonding pressures in the bonding process to reduce chiplet cracking;
depositing additional gapfill material on the surface of the substrate die and/or the surface of the chiplet subsequent to the bonding process; and
performing an annealing process, to fuse the metallic bond pads of the substrate die and the metallic bond pads of the chiplet together.

19. The method of claim 16, wherein the corrective process comprises:
halting the chip-to-substrate hybrid bonding process.

20. The method of claim 15, wherein the metallic bond pads on the substrate die and the metallic bond pads on the chiplet are disposed each in a two dimensional (2D) periodic pattern having a circular symmetry formed thereon.
